(19) United States
(12) Patent Application Publication
(10) Pub. No.: US 2012/0073628 A1
(43) Pub. Date: Mar. 29, 2012

(54) COATING AGENT FOR SOLAR CELL MODULE, AND SOLAR CELL MODULE AND PRODUCTION METHOD FOR THE SOLAR CELL MODULE

(75) Inventors: Yasuhiro Yoshida, Tokyo (JP); Yoshinori Yamamoto, Tokyo (JP); Teruhiko Kumada, Tokyo (JP)

(73) Assignee: MITSUBISHI ELECTRIC CORPORATION, Chiyoda-ku, Tokyo (JP)

(21) Appl. No.: 13/375,827

(22) PCT Filed: Jul. 6, 2010
(86) PCT No.: PCT/JP2010/061454

§ 371 Date: Dec. 2, 2011

(30) Foreign Application Priority Data
Jul. 8, 2009 (JP) 2009-161503

(51) Int. Cl. H01L 31/052; H01L 31/18; C09D 127/18; B82Y 30/00

(52) U.S. Cl. 136/246; 524/546; 438/72; 977/773; 257/E31.119

(57) ABSTRACT

The present invention relates to a coating agent for a solar cell module obtained by dispersing silica fine particles (A) with an average particle diameter of 15 nm or less and low-refractive index resin particles (B) with a refractive index of 1.36 or less in an aqueous medium, in which the solid content is 5% by mass or less, and the mass ratio of the silica fine particles (A) to the low-refractive index resin particles (B) in the solid content (silica fine particles (A)/low-refractive index resin particles (B)) is more than 20/80 and less than 70/30. The coating agent for a solar cell module is capable of forming an anti-reflection film at room temperature with excellent reflectance-reducing effect, abrasion resistance and weather resistance.

### TECHNICAL FIELD

The present invention relates to a coating agent for a solar cell module, a solar cell module and a production method for the solar cell module.

### BACKGROUND ART

The surface of a solar cell module on a light-receiving surface side is generally protected with glass such as reinforced glass, and the transmittance (reflectance) of the protective glass is known to have a large effect on photoelectric conversion efficiency.

Assuming a refractive index n₂ (n₂=1.5) of the protective glass and a refractive index n₁ (n₁=1) of air, reflectance R (R=(n₁−n₂)/(n₁+n₂)) when light is incident upon the protective glass perpendicularly is as large as 4%. Therefore, it is important to reduce the reflectance in the protective glass, and it is necessary to form an anti-reflection film from a thin film with a low-refractive index on the surface of the protective glass. If an anti-reflection film with an appropriate thickness (d=λ/4n₃, λ=wavelength, n₃=refractive index of anti-reflection film) can be formed, the reflectance can be reduced by reversing and canceling the phase of reflected light at the interface between the protective glass and the anti-reflection film. However, since the refractive index is substance specific value, the first step is appropriately selecting a material for the anti-reflection film. Further, as solar cell modules are used outdoors in many cases, it is preferable that the anti-reflection film be formed of a material having high abrasion resistance and high weather resistance, as well as a high transmittance of the wavelength range of sunlight including ultraviolet light.

A porous thin film of silica or magnesium fluoride and a thin film containing fluorine resin as a main component are known as anti-reflection films satisfying the above-mentioned demands. However, porous thin films of silica or magnesium fluoride need to be baked at high temperatures, in order to form a thin film with excellent abrasion resistance. Further, regarding thin films containing fluorine resin as a main component, the resin itself is expensive and the thin film needs to be produced using a special solvent. Consequently, it is disadvantageous to use these thin films as the anti-reflection films of solar cell modules mainly from the viewpoint of cost.

Methods of forming an anti-reflection films, which do not require the high-temperature baking or special solvents and are therefore advantageous from the viewpoint of cost have also been studied.

For example, Patent Document 1 proposes an anti-reflection film using a specific metal alkoxide oligomer as a binder of silicon dioxide. This anti-reflection film can be formed at temperature (150 to 250° C.) lower than the conventional baking temperature (about 500° C.), and has an excellent anti-reflection effect.

Further, Patent Document 2 proposes an anti-reflection film formed of a coating solution containing a metal oxide sol and metal oxide fine particles.

### CITATION LIST

### Patent Documents

Patent Document 1: JP 2007-286554 A

Patent Document 2: JP 2004-233613 A

### DISCLOSURE OF THE INVENTION

### Problems to be Solved by the Invention

However, according to the method of Patent Document 1, although the high-temperature baking at about 500° C. is not required, baking at 150 to 250° C. is still necessary, thus a sufficient cost-reducing effect in not achieved.

Further, the anti-reflection film obtained by the method of Patent Document 2 has poor transparency, cannot obtain the desired reflectance-reducing effect, and has insufficient abrasion resistance.

The present invention has been achieved in order to solve the above-mentioned problems. An object of the present invention is to provide a coating agent for a solar cell module capable of forming an anti-reflection film excellent in reflectance-reducing effect, abrasion resistance, and weather resistance at room temperature.

Another object of the present invention is to provide a solar cell module excellent in photoelectric conversion efficiency that can be produced at low cost and also a production method for this solar cell module.

### Means for Solving the Problems

As a result of earnest study to solve the above-mentioned problems, the inventors of the present invention have found that a coating agent obtained by dispersing specific silica fine particles and specific low-refractive index resin particles at a specific ratio in an aqueous solution can be used to form an anti-reflection film on a solar cell module.

That is, the present invention provides a coating agent for a solar cell module, which is obtained by dispersing silica fine particles (A) with an average particle diameter of 15 nm or less and low-refractive index resin particles (B) with a refractive index of 1.36 or less in an aqueous dispersion, the coating agent for a solar cell module comprising a solid content of 5% by mass or less and a mass ratio of silica fine particles (A) to low-refractive index resin particles (B) in the solid content (silica fine particles (A)/low-refractive index resin particles (B)) of more than 20/80 and less than 70/30.

In addition, the present invention provides a solar cell module with an anti-reflection film formed on its surface on the light-receiving surface side, in which the anti-reflection film of the solar cell module comprises low-refractive index resin particles (B) with a refractive index of 1.36 or less dispersed in a silica film formed of silica fine particles (A) with an average particle diameter of 15 nm or less and a mass ratio of silica fine particles (A) to low-refractive index resin particles (B) (silica fine particles (A)/low-refractive index resin particles (B)) of more than 20/80 and less than 70/30.

Further, the present invention provides a method of producing a solar cell module comprising applying the above-mentioned coating agent for a solar cell module to the surface of a solar cell module on a light-receiving surface side and drying the coating agent at room temperature under an airstream speed of 0.5 m/sec to 30 m/sec to form an anti-reflection film.

In addition, the present invention provides a method of producing a solar cell module comprising forming a first layer of an anti-reflection film by applying a dispersion containing 5% by mass or less of a solid content, the dispersion being obtained by dispersing silica fine particles (A) with an average particle diameter of 15 nm or less in an aqueous medium, to the surface of a solar cell module on a light-receiving surface side, and drying the dispersion, and then forming a second layer of the anti-reflection film by applying the above-mentioned coating agent for a solar cell module to the first layer of the anti-reflection film, and then drying the coating agent at room temperature under an airstream speed of 0.5 m/sec to 30 m/sec.

Further, the present invention provides a method of producing a solar cell module comprising forming a first layer of anti-reflection film by applying a dispersion containing 5% by mass or less of a solid content, the dispersion being obtained by dispersing silica fine particles (A) with an average particle diameter of 15 nm or less and one or more kinds of oxidants (D) selected from the group consisting of a peroxide, a perchlorate, a chlorate, a persulfate, a superphosphate, and a periodate in an aqueous medium, to the surface of a solar cell module on a light-receiving surface side, and drying the dispersion, and then forming a second layer of anti-reflection film by applying the above-mentioned coating agent for a solar cell module onto the first layer of anti-reflection film and then drying the coating agent at room temperature under an airstream speed of 0.5 m/sec to 30 m/sec.

### Effects of the Invention

According to the present invention, a coating agent for a solar cell module capable of forming an anti-reflection film excellent in reflectance-reducing effect, abrasion resistance and weather resistance at room temperature can be provided. In addition, according to the present invention, a solar cell module excellent in photoelectric conversion efficiency that can be produced at low cost and a production method for this solar cell module can be provided.

### BRIEF DESCRIPTION OF DRAWINGS

FIG. 1 is a cross-sectional view of a basic structure of a solar cell module.

FIG. 2 is an enlarged cross-sectional view of an anti-reflection film formed on protective glass.

FIG. 3 is an enlarged cross-sectional view of an anti-reflection film formed on the protective glass.

### MODES FOR CARRYING OUT THE INVENTION

### Embodiment 1

A coating agent for a solar cell module of this embodiment (hereinafter, merely referred to as “coating agent”) is obtained by dispersing silica fine particles (A) and low-refractive index resin particles (B) in an aqueous medium.

The silica fine particles (A) form a porous silica film when the coating agent is applied and dried. The silica film is transparent because of the presence of minute voids. Further, as the refractive index of the silica film is as low as that of the low-refractive index fine particles (B) (refractive index of SiO₂: 1.45, refractive index of a silica film with a porosity of 20%: about 1.35), it is possible to decrease the refractive index of the coating film (anti-reflection film) formed by the coating agent.

The average particle diameter of the silica fine particles (A) is 15 nm or less, preferably 12 nm or less, and more preferably 4 nm to 10 nm, when they are dispersed in water and measured by a dynamic light scattering method. Due to the coating agent containing silica fine particles (A) with an average particle diameter in this range, it is easy for the silica fine particles (A) to aggregate and the coating agent to solidify even at room temperature when the coating agent is applied and dried. Further, because the silica component that exists in solution in equilibrium in the coating agent increases, the silica component that exists in solution functions as a binder even if no specific binder is blended and an anti-reflection film having the desired strength can be formed even at room temperature. When the average particle diameter of the silica fine particles (A) exceeds 15 nm, the desired strength cannot be obtained, and the abrasion resistance of the anti-reflection film cannot be improved.

As long as the silica fine particles (A) have an average particle diameter in the above-mentioned range, the particle diameter distribution may be broader.

As well as enhancing the abrasion resistance of the anti-reflection film, the low refractive index resin particles (B) are the component which the low contribute to the low refractive index of the anti-reflection film. The low-refractive index resin particles (B) refer to resin particles having a refractive index of 1.36 or less and can be not only one type of resin particle but also a mixture of a plurality of resin particles. Further, the low-refractive index resin particles (B) may have minute pores in the particles.

Examples of the low-refractive index resin particles (B) include, but are not particularly limited to, fluorine resin particles. The fluorine resin particles are particularly suitable as they do not just have a low refractive index, they also have excellent lubricity during friction, ease of deformation and weather resistance, etc. Examples of the fluorine resin particles include PTFE (polytetrafluoroethylene, refractive index: 1.35), FEP (tetrafluoroethylene-hexafluoropropylene copolymer, refractive index: 1.34), and PFA (tetrafluoroethylene-perfluoroalkyl vinyl ether copolymer, refractive index: 1.34). PTFE, FEP, and PFA are more preferred due to their excellent stability.

The average particle diameter of the low-refractive index resin particles (B), which is not particularly limited, is preferably 250 nm or less, more preferably 50 nm to 250 nm, and most preferably 100 nm to 230 nm, when they are dispersed in water and measured by a dynamic light scattering method or by a laser diffraction method. Due to the coating agent containing the low-refractive index resin particles (B) with an average particle diameter in this range, the abrasion resistance of the anti-reflection film can be enhanced. When the average particle diameter of the low-refractive index resin particles (B) exceeds 250 nm, excessive unevenness is formed in the anti-reflection film, which causes light to be scattered and may make it impossible to obtain the desired reflectance-reducing effect. In addition, the low-refractive index resin particles (B) may detach from the anti-reflection film.

By allowing an organic solvent, a plasticizer, or the like to be present in the coating agent, the low-refractive index resin particles (B) can change their shapes when the coating agent is applied and dried, reducing excessive unevenness in the anti-reflection film, and enhancing its compatibility with the silica film formed of the silica fine particles (A). That is, the coating agent of this embodiment can contain an organic solvent, a plasticizer, or the like with the goal of obtaining the above-mentioned effects.

Examples of the organic solvent include, but are not particularly limited to, methylene chloride, methyl acetate, ethyl acetate, methyl acetoacetate, acetone, tetrahydrofuran, 1,3-dioxolane, 1,4-dioxane, cyclohexanone, ethyl formate, and 2-propanol. Examples of the plasticizer include, but are not particularly limited to, a phosphoric acid ester, a polyhydric alcohol ester, a phthalic acid ester, a citric acid ester, polyester, a fatty acid ester, and a polyvalent carboxylic acid ester.

The content of the organic solvent and the plasticizer in the coating agent is not particularly limited and may be adjusted appropriately depending upon the kind of components used.

The concentration of the silica fine particles (A) and the low-refractive index resin particles (B) that are the solid content of the coating agent has a great influence on the state of the anti-reflection film formed. Therefore, the concentration of the solid content of the coating agent needs to be 5% by mass or less, preferably 4% by mass of less, and more preferably 0.5% to 3% by mass. When the solid content exceeds 5% by mass, a large number of cracks and inconsistencies occur in the anti-reflection film formed by applying and drying the coating agent and it is apt to become an opaque film.

The mass ratio of the silica fine particles (A) to the low-refractive index resin particles (B) in the solid content (silica fine particles (A)/low-refractive index resin particles (B)) is more than 20/80 and less than 70/30, preferably 25/75 to 65/35. When the amount of the low-refractive index resin particles (B) is too small, the density of the low-refractive index resin particles (B) in the anti-reflection film becomes too small, which makes it impossible to obtain an anti-reflection film having desired abrasion resistance. On the other hand, when the amount of the low-refractive index resin particles (B) is too large, it becomes difficult to reduce the thickness of the anti-reflection film.

The aqueous medium contained in the coating agent, which is not particularly limited, is preferably water. Particularly from the viewpoint of the dispersion stability of the silica fine particles (A), the aqueous medium is preferably water containing as small an amount of mineral components as possible. When the amount of the mineral components contained in water is large, the silica fine particles (A) may aggregate to precipitate or the strength and transparency of an anti-reflection film to be formed may be degraded. Therefore, it is preferable to use deionized water. In the case where the aggregation of inorganic fine particles does not occur, tap water or the like can also be used. Further, in addition to water, a mixture of water and a polar solvent that is compatible with water can also be used from the viewpoint of adjusting, for example, the stability, coatability, and drying characteristics of the coating agent.

Examples of polar solvents include: alcohols such as ethanol, methanol, 2-propanol, and butanol; ketones such as acetone, methyl ethyl ketone, and diacetone alcohol; esters such as ethyl acetate, methyl acetate, cellosolve acetate, methyl lactate, ethyl lactate, and butyl lactate; ethers such as methyl cellosolve, cellosolve, butyl cellosolve, and dioxane; glycols such as ethylene glycol, diethylene glycol, and propylene glycol; glycol ethers such as diethylene glycol monomethyl ether, triethylene glycol monomethyl ether, propylene glycol monomethyl ether, and 3-methoxy-3-methyl-1-butanol; and glycol esters such as ethylene glycol monomethyl ether acetate, propylene glycol monomethyl ether acetate, diethylene glycol monobutyl ether acetate, and diethylene glycol monoethyl ether acetate.

In addition, the content of the aqueous medium in the coating agent, which is not particularly limited, is generally 95.0 to 99.5% by mass.

In addition to the above-mentioned components, the coating agent can contain, as part of the solid content, silica fine particles (C) with an average particle diameter of 20 nm to 50 nm. By allowing the coating agent to contain the silica fine particles (C), the porosity of the silica film can be enhanced, and the reflectance-reducing effect of the anti-reflection film can also be further enhanced.

The content of the silica fine particles (C) is preferably 5% by mass or more and less than 20% by mass with respect to the entire silica (total of the silica fine particles (A) and (B)). When the content of the silica fine particles (C) is less than 5% by mass, the effect obtained by allowing the coating agent to contain the silica fine particles (C) may not be sufficiently obtained. On the other hand, when the content of the silica fine particles (C) is equal to or more than 20% by mass, an anti-reflection film having the desired strength may not be obtained.

The coating agent can contain a surfactant, an organic solvent, and the like from the viewpoint of enhancing the coatability and drying characteristics of the coating agent and the adhesiveness and the like of the anti-reflection film. Further, the coating agent can also contain a coupling agent and a silane compound, and in the case where these components are added, an enhancing effect on the transparency and strength of the anti-reflection film can be obtained in addition to the above-mentioned effects.

The surfactant is not particularly limited, and examples thereof include various kinds of anionic or nonionic surfactants. Among the surfactants, surfactants each having low formability such as a polyoxypropylene-polyoxyethylene block polymer and a polycarboxylic type anionic surfactant are preferred because of the ease of use.

The organic solvent is not particularly limited, and examples thereof include various alcohol-based, glycol-based, ester-based, and ether-based solvents.

The coupling agent is not particularly limited, and examples thereof include amino-based coupling agents such as 3-(2-aminoethyl)aminopropyltrimethoxysilane, epoxy-based coupling agents such as 3-glycidoxypropyltrimethoxysilane, methacryloxy-based coupling agents such as 3-methacryloxypropylmethyldimethoxysilane, and mercapto-based, sulfide-based, vinyl-based, and ureido-based coupling agents.

The silane compound is not particularly limited, and examples thereof include halogen-containing compounds such as trifluoropropyltrimethoxysilane and methyltrichlorosilane, alkyl group-containing compounds such as dimethyldimethoxysilane and methyltrimethoxysilane, silazane compounds such as 1,1,1,3,3,3-hexamethyldisilazane, and oligomers such as methylmethoxysiloxane.

The contents of those components are not particularly limited as long as they are within a range not impairing the characteristics of the coating agent, and may be adjusted appropriately in accordance with the selected components.

The coating agent of this embodiment can contain an oxidant (D) from the viewpoint of enhancing the coatability with respect to a base (for example, a plastic base or a glass base) of the coating agent and the adhesiveness with respect to a base of an anti-reflection film formed of the coating agent.

The coating agent obtained by dispersing the silica fine particles (A) and the low-refractive index resin particles (B) in an aqueous medium may have poor coatability and a weak adhesion with respect to a hydrophobic surface of a plastic base, etc. and a glass base surface in which the hydrophilicity is degraded owing to surface contamination, various treatments, etc. This is caused by the following: the silica fine particles (A) have high hydrophilicity, and the low-refractive index resin particles (B) themselves have high hydrophobicity but the particles may have hydrophilicity as a result of the attachment of the surfactant to their surfaces in the coating agent. Therefore, the coating agent may not be applied sufficiently to the base or the anti-reflection film formed of the coating agent may be apt to peel off the base.

When the coating agent of this embodiment contains the oxidant (D), the surfactant in the coating agent or the anti-reflection film can be decomposed. As a result, by virtue of the presence of the exposed low-refractive index resin particles (B) having high hydrophobicity, the coatability of the coating agent with respect to a plastic base having high hydrophobicity and a glass base in which hydrophilicity is degraded, and the adhesiveness of the anti-reflection film with respect to the bases are enhanced. Further, the oxidant (D) also has a function of decomposing an organic substance on the surface of a plastic base or a glass base to generate a hydrophilic group, and this function also becomes a factor for further enhancing the coatability and the adhesiveness.

Conventionally, in the case where a hydrophilic coating film is formed on a hydrophobic plastic base or a glass base in which hydrophilicity is degraded, pre-treatments such as UV irradiation, a corona discharge treatment, a flame treatment, and soaking in a chromic acid solution or an alkaline solution are generally conducted. However, those pre-treatments can be omitted by using the coating agent containing the oxidant (D).

The oxidant (D) is not particularly limited, and any of an inorganic oxidant and an organic oxidant can be used. Among them, the following oxidant is preferred as the oxidant (D). The oxidant is soluble in water and has a function of decomposing an organic substance at room temperature. Examples of the preferred oxidant (D) include a peroxide, perchlorate, chlorate, persulfate, superphosphate, and periodate. One kind of those oxidants can be used alone, or two or more kinds thereof can be used as a mixture.

Specific examples of the inorganic oxidant include: peroxides such as hydrogen peroxide, sodium peroxide, potassium peroxide, calcium peroxide, barium peroxide, and magnesium peroxide; perchlorates such as ammonium perchlorate, sodium perchlorate, and potassium perchlorate; chlorates such as potassium chlorate, sodium chlorate, and ammonium chlorate; persulfates such as ammonium persulfate, potassium persulfate, and sodium persulfate; superphosphates such as calcium superphosphate and potassium superphosphate; and periodates such as sodium periodate, potassium periodate, and magnesium periodate.

Specific examples of the organic oxidant include a halogen benzoyl peroxide, lauroyl peroxide, acetyl peroxide, dibutyl peroxide, cumene hydroperoxide, butyl hydroperoxide, a percarbonate, sodium peracetate, potassium peracetate, m-chloroperbenzoic acid, tert-butyl perbenzoate, and a percarboxylic acid.

The content of the oxidant (D) is preferably 0.1 part by mass to 25 parts by mass, and more preferably 0.5 part by mass to 10 parts by mass with respect to 100 parts by mass of the low-refractive index resin particles (B). When the content of the oxidant (D) is less than 0.1 part by mass, a surfactant adhering to the low-refractive index resin particles (B) cannot be decomposed sufficiently in some cases. On the other hand, when the content of the oxidant (D) exceeds 25 parts by mass, the amounts of the silica fine particles (A) and the low-refractive index resin particles (B) become small, which may make it difficult to form an anti-reflection film.

The method of producing a coating agent is not particularly limited, and an aqueous medium, the silica fine particles (A), the low-refractive index resin particles (B), and any components may be mixed. Further, for example, after an aqueous dispersion of the silica fine particles (A) and a dispersion (solvent: water, an organic solvent, etc.) of the low-refractive index resin particles (B) are prepared, these aqueous dispersions may be mixed. Herein, regarding the low-refractive index resin particles (B), monomer components may be compounded as materials and then polymerized to form a polymer. Further, a surfactant may be added to the dispersion of the low-refractive index resin particles (B) so as to enhance dispersibility, or a commercially available dispersion may be used.

When the respective components are mixed, dispersants such as the above-mentioned surfactant and various inorganic salts may be compounded. Further, the dispersibility can be further enhanced by using a homogenizer or other dispersing devices for mixing, if required.

In the case of using the oxidant (D), it is preferred to compound the oxidant (D) after adding the silica fine particles (A) and the low-refractive index resin particles (B) to an aqueous medium (for example, deionized water) and mixing the contents from the viewpoint of preventing the aggregation of the low-refractive index resin particles (B). Further, in the case of using the oxidant (D), it is preferred to keep a coating agent at a temperature of 40° C. or less after compounding the oxidant and to use the coating agent within two weeks from the viewpoint of preventing the thermal decomposition of the oxidant (D).

The coating agent thus produced can form an anti-reflection film excellent in reflectance-reducing effect, abrasion resistance, and weather resistance at room temperature.

### Embodiment 2

A solar cell module of this embodiment has an anti-reflection film formed of the above-mentioned coating agent on the surface on a light-receiving surface side.

Hereinafter, an example of the solar cell module of this embodiment is described with reference to the drawings.

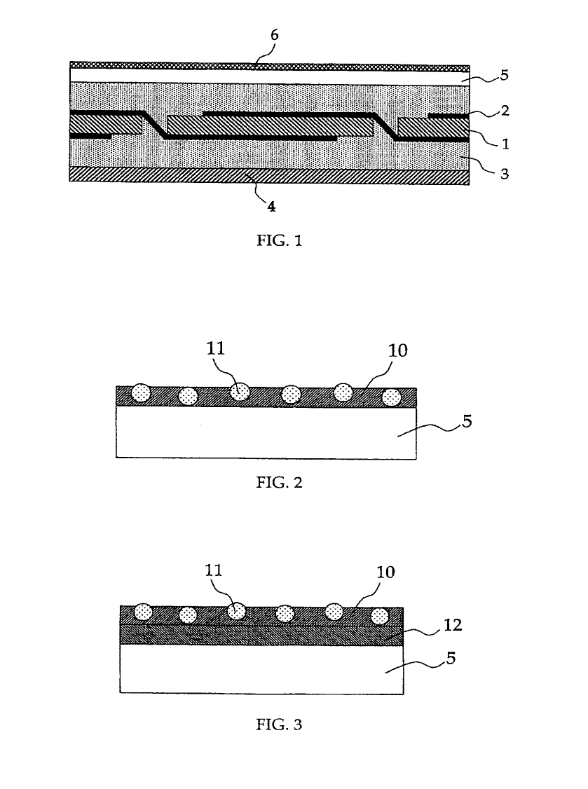

FIG. 1 is a cross-sectional view of a basic structure of the solar cell module of this embodiment. In FIG. 1, the basic structure of the solar cell module includes a plurality of solar cells 1 arranged at a predetermined interval, wires 2 connecting the plurality of solar cells 1, a transparent resin 3 sealing all of the solar cells 1 and wires 2, protective glass 5 formed on the transparent resin 3 on a light-receiving surface side, a protective film 4 formed on the transparent resin 3 on an opposite side, and an anti-reflection film 6 formed on the protective glass 5. Then, an end of the basic structure is framed with an aluminum frame or the like (not shown).

A solar cell module having such a construction is known, and can be produced using known materials except for the anti-reflection film 6.

The anti-reflection film 6 is formed on the protective glass 5 using the above-mentioned coating agent. FIG. 2 is an enlarged cross-sectional view of the anti-reflection film 6 formed on the protective glass. In FIG. 2, the anti-reflection film 6 is formed of a silica film 10 made of silica fine particles (A) and low-refractive index resin particles (B) 11 dispersed in the silica film 10. Herein, the mass ratio of the silica fine particles (A) to the low-refractive index resin particles (B) 11 (silica fine particles (A)/low-refractive index resin particles (B)) is more than 20/80 and less than 70/30.

In general, a silica film 10 formed of the silica fine particles (A) cannot obtain sufficient abrasion resistance as it is, since the binding force between particles is weak. However, the anti-reflection film 6 is provided with abrasion resistance by dispersing the low-refractive index resin particles (B) 11 in the silica film 10. That is, by setting the mass ratio between the silica fine particles (A) and the low-refractive index resin particles (B) 11 to a predetermined value, a part of the low-refractive index resin particles (B) 11 dispersed in the silica film 10 is exposed to the surface of the anti-reflection film 6. The low-refractive index resin particles (B) 11 have high flexibility and provide the anti-reflection film 6 with lubricity. For example, even when an object that causes abrasion comes into contact with the silica film 10, the low-refractive index resin particles (B) 11 come into contact with the object preferentially and allow the object to slide to reduce abrasion, thereby preventing damage to the anti-reflection film 6.

While the abrasion resistance caused when a large object comes into contact with the silica film 10 is sufficient, scratches and the like are likely to be caused in the silica film 10 by minute protrusions, etc. However, in the anti-reflection film 6 for a solar cell module, such minute scratches and the like hardly become problems.

Further, the low-refractive index resin particles (B) 11 have a low-refractive index, and hence, also provide a decreasing effect on the refractive index of the anti-reflection film.

The anti-reflection film 6 can also have a two-layered structure so as to enhance the reflectance-reducing effect. FIG. 3 is an enlarged cross-sectional view of the anti-reflection film 6 (two-layered structure) formed on the protective glass 5. In FIG. 3, the anti-reflection film 6 is formed of a first layer of a silica film 12 formed of the silica fine particles (A) and a second layer obtained by dispersing the low-refractive index resin particles (B) 11 in the silica film 10 formed of the silica fine particles (A). Herein, the mass ratio of the silica fine particles (A) to the low-refractive index resin particles (B) 11 of the second layer (silica fine particles (A)/low-refractive index resin particles (B)) is more than 20/80 and less than 70/30.

In the anti-reflection film 6 having the two-layered structure, since the refractive index of the first layer is higher than that of the second layer, the traveling direction of light incident from a diagonal direction can be brought close to a direction perpendicular to the protective glass 5 by the refraction at the layer interface. As a result, the reflectance-reducing effect can be further enhanced.

The silica film 12 of the first layer can be formed using a dispersion obtained by dispersing the silica fine particles (A) with an average particle diameter of 15 nm or less in water. A solid content (silica fine particles (A)) is 5% by mass or less of the dispersion. Further, the dispersion can contain an oxidant (D) from the viewpoint of enhancing the coatability with respect to the protective glass 5 and the adhesiveness of the silica film 12 of the first layer to the protective glass 5. Since the second layer is formed on the first layer, no abrasion resistance is required of the first layer. Therefore, it is not necessary to disperse the low-refractive index resin particles (B) in the first layer.

The thickness of the anti-reflection film 6 depends upon the wavelength of light of interest, the incident angle thereof, and the like, and hence, it is difficult to define the thickness uniquely; however, it is preferred that the thickness of the anti-reflection film 6 satisfy 2nd=½λ (n: refractive index of the anti-reflection film 6, d: film thickness of the anti-reflection film 6, λ: wavelength of incident light) from the viewpoint of obtaining the desired reflectance-reducing effect. For example, in the case of a wavelength of 550 nm and a refractive index of 1.35, the thickness of the anti-reflection film 6 is preferably about 102 nm. Since the low-refractive index resin particles (B) are dispersed in the anti-reflection film 6 obtained by the present invention, minute surface unevenness is formed and the film thickness varies locally in many cases. Thus, even when the thickness of the anti-reflection film 6 is out of the optimum film thickness satisfying the condition of the above-mentioned equation, some degree of reflectance-reducing effect is obtained.

It is preferred that the practical average thickness of the anti-reflection film 6 be 50 nm to 250 nm. Further, the upper limit of the practical thickness of the anti-reflection film 6 is more preferably 200 nm and most preferably 150 nm. When the average thickness of the anti-reflection film 6 is less than 50 nm, the desired reflectance-reducing effect cannot be obtained in some cases since the wavelength is limited to a low wavelength area. On the other hand, when the average thickness of the anti-reflection film 6 exceeds 250 nm, the film thickness portion in which the reflectance-reducing effect is obtained becomes small, which may make it impossible to obtain the desired reflectance-reducing effect. In addition, defects such as cracks and voids are caused in the anti-reflection film 6, and the anti-reflection film 6 is apt to be whitened in some cases.

A solar cell module having such a construction has the anti-reflection film 6 excellent in reflectance-reducing effect, and hence, is excellent in photoelectric conversion efficiency.

### Embodiment 3

According to a method of producing a solar cell module of this embodiment, the anti-reflection film 6 is formed at room temperature using the above-mentioned coating agent.

In the case of forming the anti-reflection film 6 having the construction of FIG. 2, it is sufficient that the above-mentioned coating agent is applied onto the surface of the solar cell module on a light-receiving surface side (that is, the protective glass 5), and is then dried at room temperature and a predetermined airstream speed.

The method of applying the coating agent is not particularly limited, and any known method may be used. Examples of the applying method include spraying, roll coating, soaking, and flowing.

The applied coating agent is dried at a predetermined airstream speed from the viewpoints of, for example, preventing the occurrence of a non-uniform thickness and enhancing the dispersibility of the low-refractive index resin particles (B) 11. The airstream that can be used is not particularly limited, and for example, air can be used. Further, the airstream speed is 0.5 m/sec to 30 m/sec, preferably 1 m/sec to 25 m/sec. When the airstream speed is less than 0.5 m/sec, the drying speed becomes low. Therefore, the silica fine particles (A) and the low-refractive index resin particles (B) 11 are apt to be separated during drying, and the anti-reflection film 6 in which the low-refractive index resin particles (B) 11 are dispersed uniformly in the silica film 10 cannot be obtained. On the other hand, when the airstream speed is more than 30 m/sec, the thickness becomes non-uniform owing to the disturbance of the airstream, and defects such as cracks and voids are generated to whiten the anti-reflection film 6. As a result, the light transparency of the anti-reflection film 6 is lost.

The above-mentioned airstream speed is also related to the refractive index of the anti-reflection film 6 to be formed. For example, in an aqueous dispersion of the silica fine particles (A) with an average particle diameter of 12 nm, in the case where there is no airstream or the airstream speed is less than 0.5 m/sec, the refractive index of the silica film to be actually formed is about 1.38. A dense silica film is supposed to have a refractive index of about 1.46; however, in a silica film actually formed, the refractive index is considered to be small owing to various factors (for example, the generation of minute voids). However, in the case where there is no airstream or the airstream speed is less than 0.5 m/sec, the refractive index cannot be decreased sufficiently, and the desired reflectance-reducing effect cannot be obtained. On the other hand, when the airstream speed is in the above-mentioned range, the refractive index of a silica film can be decreased to about 1.30 to 1.35, which is about the same as that of the low-refractive index resin particles (B).

Such relationship between the airstream speed and various properties of the anti-reflection film 6 as described above is a phenomenon seen when drying is performed at room temperature (15° C. to 35° C.). When the drying temperature is less than 15° C., the flow of the coating agent caused by the airstream is apt to occur even at an airstream speed in the above-mentioned range, and the film thickness becomes non-uniform, which makes it difficult to obtain the uniform anti-reflection film 6. On the other hand, when the drying temperature is more than 35° C., moisture components are evaporated too quickly, and hence, a non-uniform film thickness and the like occur, which makes it difficult to obtain the uniform anti-reflection film 6.

Although the anti-reflection film 6 is obtained by drying at room temperature as described above, the abrasion resistance may be further enhanced by performing heating. The heating method is not particularly limited, and for example, hot air and infrared light can be used. The heating temperature is sufficient if it reaches about 100° C. When the anti-reflection film 6 is heated to about 150° C., the abrasion resistance can be enhanced reliably.

In the case of forming the anti-reflection film 6 (two-layered structure) having the construction of FIG. 3, first, a dispersion obtained by dispersing the silica fine particles (A) with an average particle diameter of 15 nm or less in an aqueous medium is applied to the surface of a solar cell module on a light-receiving surface side (that is, the protective glass 5) and dried to form a first layer of an anti-reflection film. Herein, solid content is 5% by mass or less of the dispersion. Further, from the viewpoint of enhancing the coatability with respect to the protective glass 5 and the adhesiveness of the silica film 12 of the first layer with respect to the protective glass 5, the oxidant (D) may be compounded in the dispersion. Further, the method of applying the dispersion is not particularly limited, and any such known method as described above may be used. Further, the drying method is not particularly limited. The dispersion has only to be dried by being allowed to stand at room temperature, and there is no need to perform drying under the above-mentioned airstream.

Next, it is sufficient that the above-mentioned coating agent is applied onto the first layer, and is then dried at room temperature and a predetermined airstream speed. The applying method and drying method of the coating agent are as described above.

According to the method of producing a solar cell module, an anti-reflection film excellent in reflectance-reducing effect, abrasion resistance, and weather resistance can be formed at room temperature. Therefore, a solar cell module excellent in photoelectric conversion efficiency can be produced at low cost.

### EXAMPLES

Hereinafter, the present invention is described specifically by way of examples. However, the present invention is not limited to the following examples.

### Examples 1 to 4

Colloidal silica containing silica fine particles was added to deionized water, and the contents were mixed by stirring. Thus, an aqueous dispersion of the silica fine particles was obtained. A PTFE dispersion (31JR produced by Du Pont-Mitsui Fluorochemicals Co., Ltd.) was added to the aqueous dispersion, and the contents were mixed by stirring. After that, polyoxyethylene lauryl ether (surfactant) was further added to the mixture, and the contents were mixed by stirring. Thus, a coating agent having the composition in FIG. 1 was obtained. The compositions of the silica fine particles and the PTFE in the table correspond to the contents in the coating agents. Further, the content of the surfactant in each coating agent was set to be 0.05% by mass.

### Comparative Examples 1 to 5

Comparative Example 1 is a coating agent in which the amount of solid content, and the mass ratio between the silica fine particles and the PTFE were set to be out of predetermined ranges.

Comparative Example 2 is a coating agent in which the mass ratio between the silica fine particles and the PTFE was set to be out of the predetermined range.

Comparative Examples 3 and 4 are coating agents not containing the PTFE.

Comparative Example 5 is a coating agent containing silica fine particles with an average particle diameter out of the predetermined range.

The coating agents in those comparative examples were prepared by the same methods as those of the above-mentioned examples.

The coating agents in Examples 1 to 4 and Comparative Examples 1 to 5 were each applied to the surface of a glass plate with a spray, and then dried at room temperature and a predetermined airstream speed. Each coating film formed on the surface of the glass plates was evaluated as described below.

(Transmittance)

The transmittance was evaluated by bringing integrating spheres into contact with the reverse surface of the glass plate and measuring the transmission amount of light with a wavelength of 600 nm using a spectrophotometer UV-3100PC (produced by Shimadzu Corporation).

Herein, the transmittance of the glass plate itself was measured as a comparison. As a result, the transmittance was 88.0%.

(Abrasion Resistance)

A folded wet gauze was pressed against a coating film with a pressing surface measuring 2 cm per side, and a reciprocating motion of 10 cm was conducted under a load of 100 g/cm². The transmittance was measured every 10 times up to the 100th reciprocating motion, and every 100 times from 100th to 500th reciprocating motions, and the reciprocating number until the transmittance became half or less of the initial one was set to be an index for abrasion resistance.

Table 1 shows the evaluation results.

TABLE 1

| | Silica fine | | Drying | Average film | | |
|---|---|---|---|---|---|---|
| | particles | PTFE | conditions | thickness | Transmittance | Abrasion resistance |
| Example 1 | 0.8% by mass | 1.0% by mass | 12 m/sec | 165 nm | 89.0% | 500 times or more |
| | Average particle | Average particle | 25° C. | | | |
| | diameter 5 nm | diameter 230 nm | | | | |
| Example 2 | 1.2% by mass | 1.0% by mass | 12 m/sec | 155 nm | 89.1% | 500 times or more |
| | Average particle | Average particle | 25° C. | | | |
| | diameter 5 nm | diameter 230 nm | | | | |
| Example 3 | 2.5% by mass | 1.5% by mass | 20 m/sec | 180 nm | 88.6% | 500 times or more |
| | Average particle | Average particle | 25° C. | | | |
| | diameter 5 nm | diameter 230 nm | | | | |
| Example 4 | 1.2% by mass | 1.0% by mass | 12 m/sec | 160 nm | 89.1% | 400 times |
| | Average particle | Average particle | 25° C. | | | |
| | diameter 12 nm | diameter 230 nm | | | | |
| Comparative | 5.5% by mass | 2.0% by mass | 20 m/sec | 190 nm | 87.8% | 300 times |
| Example 1 | Average particle | Average particle | 26° C. | | | |
| | diameter 5 nm | diameter 230 nm | | | | |
| Comparative | 0.2% by mass | 1.0% by mass | 12 m/sec | 145 nm | 89.8% | 100 times |
| Example 2 | Average particle | Average particle | 25° C. | | | |
| | diameter 5 nm | diameter 230 nm | | | | |
| Comparative | 1.2% by mass | — | 12 m/sec | 120 nm | 89.8% | 20 times |
| Example 3 | Average particle | | 25° C. | | | |
| | diameter 5 nm | | | | | |
| Comparative | 1.2% by mass | — | 12 m/sec | 108 nm | 90.2% | 10 times or less |
| Example 4 | Average particle | | 25° C. | | | |
| | diameter 12 nm | | | | | |
| Comparative | 1.2% by mass | 1.0% by mass | 12 m/sec | 160 nm | 89.4% | 80 times |
| Example 5 | Average particle | Average particle | 25° C. | | | |
| | diameter 26 nm | diameter 230 nm | | | | |

As is shown in the results of Table 1, each of the coating films formed of the coating agents of Examples 1 to 4 have a satisfactory transmittance and satisfactory abrasion resistance, and are suitable for use as an anti-reflection film.

On the other hand, the coating film formed of the coating agent of Comparative Example 1 in which the amount of the solid content and the mass ratio of the silica fine particles with respect to the PTFE are too large has a transmittance lower than that of the glass plate itself and is not suitable for use as an anti-reflection film. Further, the coating agent of Comparative Example 2 in which the mass ratio of the silica fine particles with respect to the PTFE is too small has insufficient abrasion resistance and is not suitable for use as an anti-reflection film. Similarly, each of the coating films formed of the coating agents of Comparative Examples 3 and 4 not containing the PTFE, and the coating agent of Comparative Example 5 using the silica fine particles having too large an average particle diameter have insufficient abrasion resistance and are not suitable for use as an anti-reflection film.

### Examples 5 to 7 and Comparative Examples 6 to 8

Colloidal silica containing silica fine particles with an average particle diameter of 5 nm was added to deionized water, and the contents were mixed by stirring. Thus, an aqueous dispersion of the silica fine particles was obtained. Next, a PTFE powder (L173J produced by Asahi Glass Co., Ltd.) with an average particle diameter of 180 nm and a surfactant (F-410 produced by DIC Corporation) were added to deionized water and dispersed using a dispersing device (Nanomizer produced by Yoshida Kikai Co., Ltd.). Thus, an aqueous dispersion of the PTFE powder was obtained. Then, the aqueous dispersion of the silica fine particles and the aqueous dispersion of the PTFE powder were mixed by stirring. Further, 2-propanol was added to the mixture, and the contents were mixed by stirring. Thus, a coating agent was obtained. Herein, the content of the silica fine particles in the coating agent was 1.0% by mass, the content of the PTFE was 0.4% by mass, the content of the surfactant was 0.1% by mass, and the content of 2-propanol was 10% by mass.

The coating agent thus obtained was applied to the surface of a glass plate with a spray, and thereafter, dried at room temperature and a predetermined airstream speed. The coating films formed with various drying conditions (airstream speed and drying temperature) were each evaluated for transmittance and abrasion resistance in the same way as that described above. Table 2 shows the results.

TABLE 2

| | Drying | Average film | Transmit- | Abrasion |
|---|---|---|---|---|
| | conditions | thickness | tance | resistance |
| Example 5 | 1 m/sec | 145 nm | 89.1% | 400 times |
| | 25° C. | | | |
| Example 6 | 12 m/sec | 134 nm | 89.4% | 500 times |
| | 25° C. | | | or more |
| Example 7 | 25 m/sec | 120 nm | 90.2% | 500 times |
| | 25° C. | | | or more |
| Comparative | 0 m/sec | 162 nm | 88.6% | 100 times |
| Example 6 | 25° C. | | | |
| Comparative | 35 m/sec | 98 nm | 87.9% | — |
| Example 7 | 25° C. | | | |
| Comparative | 12 m/sec | 165 nm | 88.6% | 90 times |
| Example 8 | 45° C. | | | |

As is shown in the results of Table 2, each of the coating films dried under the drying conditions of Examples 5 to 7 have satisfactory transmittance and satisfactory abrasion resistance, and are suitable for use as an anti-reflection film.

On the other hand, the coating film of Comparative Example 6 that had not been dried under an airstream had insufficient abrasion resistance. Further, the coating film of Comparative Example 7 that had been dried under a condition where the airstream speed had been too high became opaque and had a number of irregularities and low transmittance. In Comparative Example 7, since the transmittance was low, the abrasion resistance was not measured. Further, the coating film of Comparative Example 8 that had been dried under a condition where the drying temperature had been too high had insufficient abrasion resistance.

### Examples 8 and 9

In Examples 8 and 9, coating agents each containing two kinds of silica fine particles were prepared.

Specifically, colloidal silica containing silica fine particles was added to deionized water, and the contents were mixed by stirring. Thus, an aqueous dispersion of the silica fine particles was obtained. A PTFE dispersion (AD911 produced by Asahi Glass Co., Ltd.) was added to the aqueous dispersion, and the contents were mixed by stirring. Thus, coating agents having the compositions in Table 3 were obtained. The compositions of the silica fine particles and the PTFE in the table correspond to the contents in the coating agents.

Each of the coating agents thus obtained were applied to the surface of a glass plate with a spray, and thereafter, dried at room temperature and a predetermined airstream speed. The coating films formed on the surface of the glass plate were evaluated for transmittance and abrasion resistance in the same way as in the foregoing. Table 3 shows the results.

TABLE 3

| | | | | Drying | Average film | | |
|---|---|---|---|---|---|---|---|
| | Silica fine particles | | PTFE | conditions | thickness | Transmittance | Abrasion resistance |
| Example 8 | 1.0% by mass | 0.1% by mass | 0.5% by mass | 1 m/sec | 145 nm | 89.1% | 400 times |
| | Average particle | Average particle | Average particle | 25° C. | | | |
| | diameter 5 nm | diameter 25 nm | diameter 210 nm | | | | |
| Example 9 | 1.0% by mass | 0.1% by mass | 0.5% by mass | 12 m/sec | 134 nm | 89.4% | 500 times or more |
| | Average particle | Average particle | Average particle | 25° C. | | | |
| | diameter 5 nm | diameter 25 nm | diameter 210 nm | | | | |

As shown in the results of Table 3, each of the coating films formed of the coating agents of Examples 8 and 9 each containing two kinds of silica fine particles had high transmittance and satisfactory abrasion resistance, and are suitable for use as an anti-reflection film.

### Examples 10 and 11

In Examples 10 and 11, coating films each having a two-layered structure were formed.

A coating agent (aqueous dispersion of silica fine particles) for forming a first layer was obtained by adding colloidal silica containing the silica fine particles to deionized water and mixing the contents by stirring.

A coating agent for forming a second layer was obtained in the same way as in Examples 1 to 4.

Table 4 shows the compositions of the coating agents. The compositions of the silica fine particles and the PTFE in the table correspond to the contents in the respective coating agents.

The coating agent for forming a first layer was applied to the surface of a glass plate with a spray and then allowed to stand still at room temperature (25° C.). Thus, a first layer was formed.

Next, the coating agent for forming a second layer was applied onto the first layer with a spray and then dried at room temperature (25° C.) and an airstream speed of 2 m/sec.

The coating film with a two-layered structure formed on the surface of the glass plate was evaluated for transmittance and abrasion resistance in the same way as in the foregoing. Table 4 shows the results.

TABLE 4

| | First layer | | Second layer | | Average film thickness | | |
|---|---|---|---|---|---|---|---|
| | Silica | Average | Silica | | (first layer + | Transmit- | |
| | fine particles | film thickness | fine particles | PTFE | second layer) | tance | Abrasion resistance |
| Example 10 | 0.5% by mass | 55 nm | 0.5% by mass | 0.5% by mass | 165 nm | 89.9% | 500 times or more |
| | Average particle | | Average particle | Average particle | | | |
| | diameter 5 nm | | diameter 5 nm | diameter 210 nm | | | |
| Example 11 | 0.2% by mass | 36 nm | 0.5% by mass | 0.5% by mass | 148 nm | 90.4% | 500 times or more |
| | Average particle | | Average particle | Average particle | | | |
| | diameter 5 nm | | diameter 5 nm | diameter 210 nm | | | |

As is shown in the results of Table 4, each of the coating films of Examples 10 and 11 each having a two-layered structure have high transmittance and are excellent in abrasion resistance, and are suitable for use as an anti-reflection film.

### Examples 12 to 14

Colloidal silica containing silica fine particles was added to deionized water, and the contents were mixed by stirring. Thus, an aqueous dispersion of the silica fine particles was obtained. A PTFE dispersion (31JR produced by Du Pont-Mitsui Fluorochemicals Co., Ltd.) was added to the aqueous dispersion, and the contents were mixed by stirring. After that, polyoxyethylene lauryl ether (surfactant) and an oxidant were further added to the mixture, and the contents were mixing by stirring. Thus, a coating agent having a composition in Table 5 was obtained. The compositions of the silica fine particles, the PTFE, and the oxidant in the table correspond to the contents in the coating agents. Further, the content of the surfactant in each coating agent was set to be 0.05% by mass.

Each of the coating agents of Examples 12 to 14 and the coating agent of Example 1 not containing any oxidant as a comparison of these coating agents were applied to the surface of a glass plate with a spray and then dried at 25° C. under an airstream of 12 m/sec. The coating films each formed on the surface of a glass plate were each evaluated for transmittance and abrasion resistance in the same way as in the foregoing. Regarding the abrasion resistance, a test using a load of 250 g/cm² was also conducted in addition to a test using a load of 100 g/cm².

Table 5 shows the results. In Table 5, the results of the test for abrasion resistance using a load of 250 g/cm² are represented as “abrasion resistance (strong).”

TABLE 5

| | | | | Average film | Transmit- | | Abrasion resistance |
|---|---|---|---|---|---|---|---|
| | Silica fine particles | PTFE | Oxidant | thickness | tance | Abrasion resistance | (strong) |
| Example 12 | 0.8% by mass | 1.0% by mass | 0.2% by mass | 160 nm | 91.8% | 500 times or more | 400 times |
| | Average particle | Average particle | Acetyl peroxide | | | | |
| | diameter 5 nm | diameter 230 nm | | | | | |
| Example 13 | 0.8% by mass | 1.0% by mass | 0.2% by mass | 158 nm | 89.4% | 500 times or more | 500 times or more |
| | Average particle | Average particle | Sodium peroxide | | | | |
| | diameter 5 nm | diameter 230 nm | | | | | |
| Example 14 | 0.8% by mass | 1.5% by mass | 0.5% by mass | 155 nm | 90.0% | 500 times or more | 400 times |
| | Average particle | Average particle | Hydrogen peroxide | | | | |
| | diameter 5 nm | diameter 230 nm | | | | | |
| Example 1 | 0.8% by mass | 1.0% by mass | — | 164 nm | 89.0% | 500 times or more | 300 times |
| (for comparison) | Average particle | Average particle | | | | | |
| | diameter 5 nm | diameter 230 nm | | | | | |

As is shown in the results of Table 5, the coating films formed of the coating agents of Examples 12 to 14 each containing an oxidant each have a transmittance and abrasion resistance equal to or more than those of the coating film formed of the coating agent of Example 1 not containing any oxidant, and are each suitable for use as an anti-reflection film. In particular, regarding the coating films formed of the coating agents of Examples 12 to 14, the results that were more satisfactory than those of the coating film formed of the coating agent of Example 1 were obtained in the test for abrasion resistance in which a load was increased, and it was found that the addition of an oxidant enhanced abrasion resistance.

As can be seen from the foregoing results, according to the present invention, there can be provided a coating agent for a solar cell module capable of forming an anti-reflection film excellent in reflectance-reducing effect, abrasion resistance, and weather resistance at room temperature. In addition, according to the present invention, a solar cell module excellent in photoelectric conversion efficiency that can be produced at low cost and a production method therefor can be provided.

This international application claims priority from Japanese Patent Application No. 2009-161503, filed on Jul. 8, 2009, the entire disclosure of which is incorporated herein by reference.

1. A coating agent prepared by a process comprising dispersing silica fine particles (A) having an average particle diameter of 15 nm or less and low-refractive index resin particles (B) having a refractive index of 1.36 or less in an aqueous medium,
wherein the coating agent has a solid content of 5% by mass or less, and a mass ratio of the silica fine particles (A) to the low-refractive index resin particles (B) in the solid content is more than 20/80 and less than 70/30.

2. The coating agent of claim 1, wherein the low-refractive index resin particles (B) have an average particle diameter of 250 nm or less.

3. The coating agent of claim 1, wherein the low-refractive index resin particles (B) comprises fluorine resin particles.

4. The coating agent of claim 1, wherein the process further comprises dispersing silica fine particles (C) having an average particle diameter of 20 nm to 50 nm, wherein an amount of the silica fine particles (C) is 5% by mass or more and 20% by mass or less of a total mass of the silica fine particles (A) and (C).

5. The coating agent of claim 1, wherein the process further comprises dispersing at least one oxidant (D) selected from the group consisting of a peroxide, a perchlorate, a chlorate, a persulfate, a superphosphate, and a periodate.

6. A solar cell module, comprising an anti-reflection film on a surface of the solar cell module on light-receiving surface side,
wherein the anti-reflection film comprises low-refractive index resin particles (B) having a refractive index of 1.36 or less dispersed in a silica film comprising silica fine particles (A) having an average particle diameter of 15 nm or less, and
wherein a mass ratio of the silica fine particles (A) to the low-refractive index resin particles (B) is more than 20/80 and less than 70/30.

7. The solar cell module of claim 6, wherein the low-refractive index resin particles (B) have an average particle diameter of 250 nm or less.

8. The solar cell module of claim 6, wherein the low-refractive index resin particles (B) comprise fluorine resin particles.

9. The solar cell module of claim 6, wherein the silica film further comprises silica fine particles (C) having an average particle diameter of 20 nm to 50 nm, and
wherein an amount of the silica fine particles (C) is 5% by mass or more and 20% by mass or less of a total mass of the silica fine particles (A) and (C).

10. The solar cell module of claim 6, wherein the anti-reflection film comprises
a first layer comprising a first silica film comprising the silica fine particles (A) and
a second layer obtained by a process comprising dispersing the low-refractive index resin particles (B) in a second silica film comprising the silica fine particles (A) wherein a mass ratio of the silica fine particles (A) to the low-refractive index resin particles (B) is more than 20/80 and less than 70/30.

11. The solar cell module of claim 6, wherein the anti-reflection film has an average thickness of 50 nm to 250 nm.

12. A method for producing a solar cell module, the method comprising:
applying the coating agent of claim 1 with a surface of a solar cell module on a light-receiving surface side; and
drying the coating agent at room temperature and with an airstream speed of 0.5 m/sec to 30 m/sec to obtain an anti-reflection film.

13. A method for producing a solar cell module, the method comprising:
(I) contacting dispersion comprising 5% by mass or less of a solid content, the dispersion obtained by a process comprising dispersing silica fine particles (A) having an average particle diameter of 15 nm or less in an aqueous medium, with a surface of a solar cell module on a light-receiving surface side, and drying the dispersion, to obtain a first layer of an anti-reflection film; and then
(II) contacting the coating agent of claim 1, with the first layer of the anti-reflection film and then drying the coating agent at room temperature and with an airstream speed of 0.5 msec to 30 msec, to obtain a second layer of the anti-reflective film.

14. A method for producing a solar cell module, the method comprising:
(I) contacting a dispersion having a solid content of 5% by mass or less, the dispersion obtained by a process comprising dispersing silica fine particles (A) having an average particle diameter of 15 nm or less and at least one oxidant (D) selected from the group consisting of a peroxide, a perchlorate, a chlorate, a persulfate, a superphosphate, and a periodate in an aqueous medium, with a surface of a solar cell module on a light-receiving surface side, and drying the dispersion, to obtain a first layer of an anti-reflection film; and then
(II) contacting the coating agent of claim 1 with the first layer of the anti-reflection film, and then drying the coating agent at room temperature and with an airstream speed of 0.5 msec to 30 msec, to obtain a second layer of the anti-reflection film.

15. The coating agent of claim 1, wherein the silica fine particles (A) have an average particle diameter of 12 nm or less.

16. The coating agent of claim 1, wherein the silica fine particles (A) have an average particle diameter of 4 to 10 nm.

17. The coating agent of claim 3, wherein the fluorine resin particles comprise at least one selected from the group consisting of polytetrafluoroethylene, tetrafluoroethylene-hexafluoropropylene copolymer, and tetrafluoroethylene-perfluoroalkyl vinyl ether copolymer.

18. The coating agent of claim 1, wherein the low-refractive index particles (B) have an average particle diameter of 50 to 250 nm.

19. The coating agent of claim 1, wherein the low-refractive index particles (B) have an average particle diameter of 100 to 230 nm.

20. The coating agent of claim 1, wherein the coating agent has a solid content of 0.5 to 3% by mass.
